(19) United States
(12) Patent Application Publication
(10) Pub. No.: US 2026/0299177 A1
(43) Pub. Date: Oct. 1, 2026

(54) CURABLE COMPOSITION, CURED LAYER USING THE COMPOSITION, AND DISPLAY DEVICE INCLUDING THE CURED LAYER

(71) Applicant: SAMSUNG SDI CO., LTD., Yongin-si, Gyeonggi-do (KR)

(72) Inventors: Jihyeon YIM, Suwon-si (KR); Yonghee KANG, Suwon-si (KR); Kyunghee KANG, Suwon-si (KR); Hyunjoo HAN, Suwon-si (KR); Chul-Kyu KIM, Suwon-si (KR); Sohyun KIM, Suwon-si (KR); Bumjin LEE, Suwon-si (KR)

(21) Appl. No.: 19/469,318

(22) PCT Filed: Mar. 13, 2024
(86) PCT No.: PCT/KR2024/003243

§ 371 Date: Sep. 25, 2025

(30) Foreign Application Priority Data
Mar. 29, 2023 (KR) 10-2023-0041364
Aug. 29, 2023 (KR) 10-2023-0113814

(51) Int. Cl. G02B 5/20; B82Y 20/00; C09K 11/02; C09K 113/00; G02B 1/04

(52) U.S. Cl. CPC G02B 5/206; B82Y 20/00; C09K 11/025; G02B 1/04; G02B 5/207; C09K 2113/00

(57) ABSTRACT

Provided are a curable composition including (A) quantum dots including a structural unit represented by Chemical Formula 1; and (B) a polymerizable compound, a cured layer produced using the curable composition, and a display device including the cured layer.

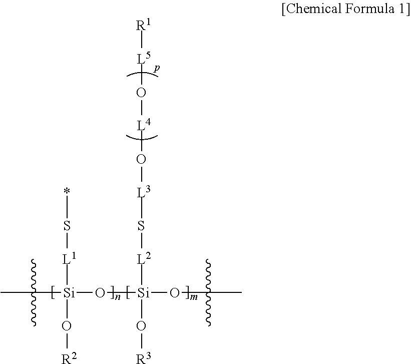

In Chemical Formula 1, each substituent is as defined in the specification.

### TECHNICAL FIELD

The present disclosure relates to a curable composition, a cured layer produced using the composition, and a display device including the cured layer.

### BACKGROUND ART

In the case of general quantum dots, due to surface characteristics having hydrophobicity, a solvent in which it is dispersed is limited, and thus, it is difficult to introduce into a polar system such as a binder or a curable monomer.

For example, even in the case of a quantum dot ink composition being actively researched, a polarity is relatively low in an initial step and it may be dispersed in a solvent used in a curable composition having a high hydrophobicity. Therefore, because 20 wt % or more of quantum dots are difficult to be included based on a total amount of the composition, it is impossible to increase light efficiency of the ink over a certain level. Even though the quantum dots are additionally added and dispersed in order to increase light efficiency, a viscosity exceeds a range capable of ink-jetting and thus processability may not be satisfied.

In order to achieve the viscosity range capable of ink-jetting, a method of lowering an ink solid content by dissolving 50 wt % or more of a solvent based on a total amount of the composition, which also provides a somewhat satisfactory result in terms of viscosity. However, it may be considered to be a satisfactory result in terms of a viscosity, but nozzle drying due to solvent volatilization, nozzle clogging, and a thickness reduction of single film as time passed after jetting may become worse and it is difficult to control a thickness deviation after curing. Thus, it is difficult to apply it to actual processes.

Therefore, a solvent-free quantum dot ink that does not include a solvent is the most desirable form to be applied to an actual process. The current technique of applying a quantum dot itself to a solvent-type composition is now limited to a certain extent.

### DISCLOSURE

### Technical Problem

An embodiment provides a curable composition having excellent light resistance reliability.

Another embodiment provides a cured layer produced using the curable composition.

Another embodiment provides a display device including the cured layer.

### Technical Solution

An embodiment provides a curable composition including (A) quantum dots including a structural unit represented by Chemical Formula 1; and (B) a polymerizable compound.

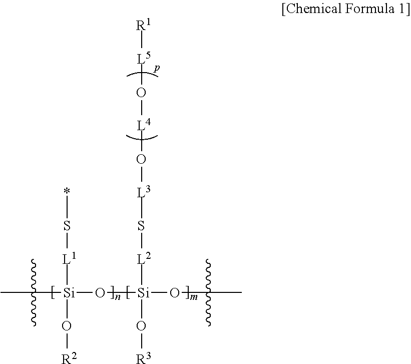

In Chemical Formula 1,
R¹ is a substituted or unsubstituted C2 to C20 heterocycloalkyl group or a substituted or unsubstituted C6 to C20 aryl group,
R² and R³ are each independently a hydrogen atom or a substituted or unsubstituted C1 to C20 alkyl group,
L¹ to L⁵ are each independently a substituted or unsubstituted C1 to C20 alkylene group,
n and m are each independently 1 to 100,
p is an integer from 1 to 20, and
* is a linking portion with the quantum dots.

The n:m may have an equivalence ratio of 1:1.5 to 1:9.

The substituted or unsubstituted C2 to C20 heterocycloalkyl group may be represented by Chemical Formula R-1.

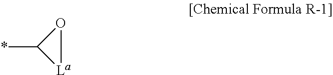

In Chemical Formula R-1,
L^{a} is a substituted or unsubstituted C2 to C10 alkylene group.

The polymerizable compound may be represented by Chemical Formula 2.

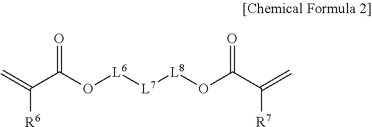

In Chemical Formula 2,
R⁶ and R⁷ are each independently a hydrogen atom or a substituted or unsubstituted C1 to C10 alkyl group,
L⁶ and L⁸ are each independently a single bond or a substituted or unsubstituted C1 to C10 alkylene group, and
L⁷ is a substituted or unsubstituted C1 to C10 alkylene group, a substituted or unsubstituted C3 to C20 cycloalkylene group, or an ether group (*—O—*).

The polymerizable compound may be represented by Chemical Formula 2-1 or 2-2.

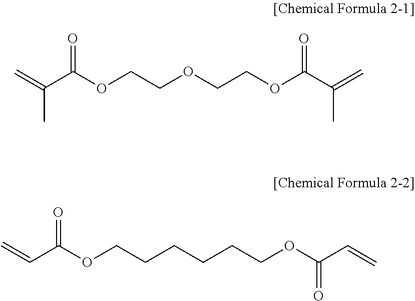

The curable composition may be a solvent-free curable composition.

The solvent-free curable composition may include 5 wt % to 60 wt % of the quantum dots; and 40 wt % to 95 wt % of the polymerizable compound based on a total amount of the solvent-free curable composition.

The curable composition may further include a polymerization initiator, a light diffusing agent, a polymerization inhibitor, or a combination thereof.

The light diffusing agent may include barium sulfate, calcium carbonate, titanium dioxide, zirconia, or a combination thereof.

The curable composition may further include a solvent.

The curable composition may include 1 wt % to 40 wt % of the quantum dots; 1 wt % to 20 wt % of the polymerizable compound; and 40 wt % to 80 wt % of the solvent based on a total weight of the curable composition.

The curable composition may further include malonic acid; 3-amino-1,2-propanediol; a silane-based coupling agent; a leveling agent; a fluorine-based surfactant; or a combination thereof.

The quantum dots may be quantum dots surface-modified with a compound having a structure represented by Chemical Formula 3.

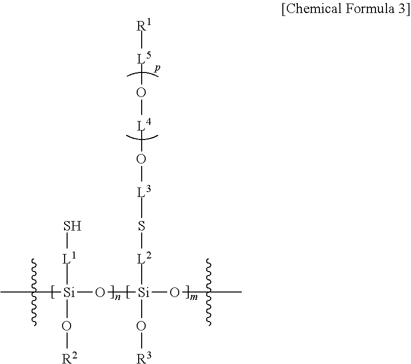

In Chemical Formula 3,
R¹ is a substituted or unsubstituted C2 to C20 heterocycloalkyl group or a substituted or unsubstituted C6 to C20 aryl group,
R² and R³ are each independently a hydrogen atom or a substituted or unsubstituted C1 to C20 alkyl group,
L¹ to L⁵ are each independently a substituted or unsubstituted C1 to C20 alkylene group,
n and m are each independently from 1 to 100, and
p is an integer from 1 to 20.

Another embodiment provides a cured layer produced using the curable composition.

Another embodiment provides a display device including the cured layer.

Other embodiments of the present invention are included in the following detailed description.

### Advantageous Effects

By modifying the structure of the surface-modifying material for modifying the surface of the quantum dots in the curable composition containing quantum dots, light resistance reliability of the quantum dot-containing curable composition may be greatly improved.

### BEST MODE

Hereinafter, embodiments of the present invention are described in detail. However, these embodiments are exemplary, the present invention is not limited thereto and the present invention is defined by the scope of claims.

In the present specification, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

In the present specification, when specific definition is not otherwise provided, “substituted” refers to replacement of at least one hydrogen atom by a substituent selected from a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

In the present specification, when specific definition is not otherwise provided, “hetero” refers to inclusion of at least one heteroatom of N, O, S, and P, in the chemical formula.

In the present specification, when specific definition is not otherwise provided, “(meth)acrylate” refers to both “acrylate” and “methacrylate”, and “(meth)acrylic acid” refers to “acrylic acid” and “methacrylic acid”.

In the present specification, when specific definition is not otherwise provided, the term “combination” refers to mixing or copolymerization.

In the present specification, when a definition is not otherwise provided, hydrogen is bonded at the position when a chemical bond is not drawn in chemical formula where supposed to be given.

In the present specification, when specific definition is not otherwise provided, “ [symbol] ” means a moiety connected to the same or different atoms or chemical formulas.

In quantum dot display-related applications, quantum dots should have several main properties such as viscosity and the like, among which the most important properties are high luminance of the quantum dots on a display and reliability of maintaining the luminance. In terms of the luminance, it is highly likely to express characteristics of quantum dot particles themselves, but in particular, in terms of the reliability, there are still many barriers to overcome.

This is because the quantum dot is vulnerable to oxygen, heat, light, etc. due to their characteristics, and lots of efforts to overcome this have been made through various methods. A technology known so far all relates to a method of encapsulating the quantum dot surface with a polymer material including a heat resistance functional group and the like, passivating the quantum dot surface with aluminum, titanium, or an oxide thereof, or the like. Recently, attempts to simultaneously increase the luminance with durability by doping a small amount of a transition metal (Cu, Mg, etc.) component in the synthesis of the quantum dot are being made.

As described above, since the reliability of maintaining the luminance is the most important property of the quantum dot, the present inventors have reviewed the research results published so far and confirmed possibility of improving light resistance reliability by passivating the quantum dot surface with a small amount of silica, which is stable to light, completing the present invention after many trials and errors and failures. Although the silica is chemically stable to light, the present inventors have spent a lot of time and effort to identify the most suitable silica structure and finally succeeded in inventing a structure of a quantum dot surface-modifying material capable of maximizing improvement of the light resistance reliability by using a polymer instead of a monomer as the quantum dot surface-modifying material and polymerizing a siloxane-based monomer having a thiol group at the terminal end and a siloxane-based monomer having an aromatic ring or a heterocyclic ring at the terminal end to obtain the polymer.

The structure invented by the present inventors exhibits excellent compatibility with currently-used ligands, and in addition, dispersibility of the quantum dot and compatibility with other components in a quantum dot-containing curable composition are satisfactory. In addition, the durability of the quantum dot itself can be greatly increased. Specifically, the light resistance reliability is improved by the siloxane-based monomer having a thiol group at the terminal end, but when the siloxane-based monomer having a thiol group at the terminal end is used alone, it is not dispersed in a polymerizable monomer and thus may not be used particularly in a solvent-free curable composition. However, according to an embodiment, the siloxane-based monomer having a thiol group at the terminal end and the siloxane-based monomer having an aromatic ring or a heterocyclic ring at the terminal end are polymerized into the polymer, significantly improving dispersibility of the quantum dot surface-modifying material in the polymerizable monomer and ultimately contributing to significantly improving the light resistance reliability of the solvent-free curable composition.

Hereinafter, each component constituting the curable composition according to an embodiment will be described in detail.

### Quantum Dots

The quantum dots in the curable composition according to an embodiment include a structural unit represented by Chemical Formula 1.

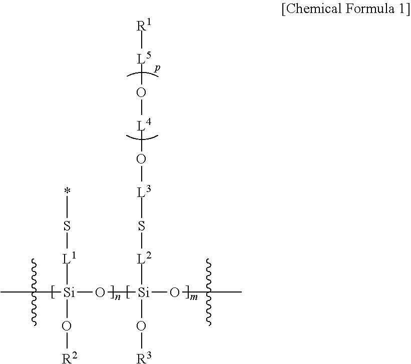

In Chemical Formula 1,
R¹ is a substituted or unsubstituted C2 to C20 heterocycloalkyl group or a substituted or unsubstituted C6 to C20 aryl group,
R² and R³ are each independently a hydrogen atom or a substituted or unsubstituted C1 to C20 alkyl group,
L¹ to L⁵ are each independently a substituted or unsubstituted C1 to C20 alkylene group,
n and m are each independently 1 to 100,
p is an integer from 1 to 20, and
* is a linking portion with the quantum dots.

The structural unit represented by Chemical Formula 1 is derived from a compound represented by Chemical Formula 3, and the quantum dots of the present invention may be obtained by surface-modification with a compound having a structure represented by Chemical Formula 3.

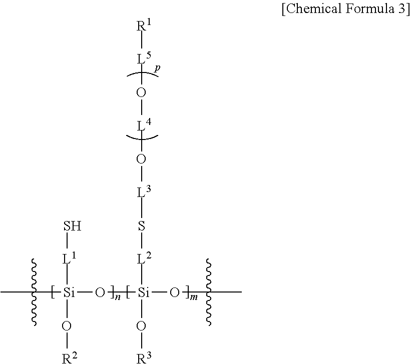

In Chemical Formula 3,
R¹ is a substituted or unsubstituted C2 to C20 heterocycloalkyl group or a substituted or unsubstituted C6 to C20 aryl group,
R² and R³ are each independently a hydrogen atom or a substituted or unsubstituted C1 to C20 alkyl group,
L¹ to L⁵ are each independently a substituted or unsubstituted C1 to C20 alkylene group,
n and m are each independently 1 to 100, and
p is an integer from 1 to 20.

In general, a method of encapapsulating a quantum dot with a siloxane-based monomer is to add TEOS (tetraethyl orthosilicate) and H₂O to MPTMS (3-mercaptopropy trimethoxysilane) or MPMDMS (3-mercaptopropyl methyl dimethoxysilane) to proceed with a sol-gel reaction. This reaction, which has to go through two or more steps, takes a long time and has disadvantages of deteriorating quantum efficiency of the quantum dot and also, difficulties of analyzing and confirming a degree of the reaction in each step.

As described above, since reliability of maintaining luminance even in strong BLU light has been reported to be the most important property of QD, a main purpose of the present invention is to improve the light resistance reliability of QD by passivating the QD surface with a silane binder, which is stable to BLU light on, instead of conventional ligands.

Since silica or silane is chemically stable, the present inventors have introduced the siloxane-based monomer into which a thiol group is introduced at the terminal end, so that this monomer may serve as a site substituted with a ligand and as a silica matrix. In addition, in order to increase the dispersibility of the siloxane-based monomer into which the thiol group is introduced in a polymerizable monomer (specifically, dispersibility of a surface-modified quantum dot in a polymerizable monomer), a novel ligand (a quantum dot surface-modifying material) is synthesized as a polymer by polymerizing the siloxane-based monomer into which an aromatic ring or a heterocyclic ring is introduced at the terminal end with the siloxane-based monomer into which the thiol group is introduced at the terminal end. Specifically, the two materials (the siloxane-based monomer into which the thiol group is introduced at the terminal end and the siloxane-based monomer into which an aromatic ring or a heterocyclic ring is introduced at the terminal end) are split (divided) by a content to proceed with the sol-gel reaction, obtaining a silane ligand and specifically, a compound including a structural unit represented by Chemical Formula 3.

The prepared ligand as described above is applied to the quantum dot to modify the surface of the quantum dot, obtaining the quantum dot including the structural unit represented by Chemical Formula 1. The silane ligand, since a ligand exchange reaction easily proceeds, exhibits excellent dispersibility of the quantum dot and in addition, satisfactory compatibility with other components in the curable composition. Furthermore, the silane ligand is not a monomer but a polymer and thus has a relatively large size, improving durability of the entire curable composition.

For example, the compound (polymer) including the structural unit represented by Chemical Formula 3 may have a weight average molecular weight of 1,000 g/mol to 10,000 g/mol. If the compound has a weight average molecular weight within the above range, the ligand substitution reaction proceeds well, so that the compound (polymer) including the structural unit represented by Chemical Formula 3 can well encapsulate the quantum dots.

For example, the n:m may have an equivalence ratio of 1:1.5 to 1:9. The ratio between the thiol group and the aromatic ring or heterocyclic ring in the polymer is determined according to the above equivalence ratio. According to an embodiment, when n and m have an equivalence ratio within the above range, a ligand substitution reaction may easily occur. When n:m is 1:10, the equivalent weight of the siloxane-based ligand containing a thiol group at the terminal is relatively low, making it difficult for a ligand substitution reaction to occur easily, and when n:m is 1:1, optical characteristics may be deteriorated rapidly, and light resistance reliability may be also inferior.

For example, in Chemical Formulas 1 and 3, the substituted or unsubstituted C2 to C20 heterocycloalkyl group may be represented by Chemical Formula R-1.

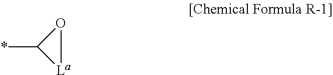

In Chemical Formula R-1,

L^{a} is a substituted or unsubstituted C2 to C10 alkylene group.

In Chemical Formulas 1 and 3, when R¹ is represented by Chemical Formula R-1, dispersibility of the siloxane-based ligand (polymer) for the polymerizable monomers may be further improved. In particular, the dispersibility for the polymerizable monomers represented by Chemical Formula 2 may be maximized. In addition, it may have a positive effect on achieving low viscosity and outgas reduction through improved dispersibility for polymerizable monomers described later, and may be particularly desirable for implementing a solvent-free curable composition.

For example, when the curable composition according to an embodiment is a solvent-free curable composition, an amount of the quantum dots may be 5 wt % to 60 wt %, for example 10 wt % to 60 wt %, for example 20 wt % to 60 wt %, for example 30 wt % to 50 wt %. If the quantum dots are included within the range, high light retention and light efficiency may be achieved even after curing.

For example, when the curable composition according to an embodiment is a curable composition including a solvent, the quantum dots may be included in an amount of a 1 wt % to 40 wt %, for example 3 wt % to 30 wt %, based on a total amount of the curable composition. When the quantum dots are included within the above range, the light conversion rate and pattern characteristics may be excellent.

For example, the quantum dots absorb light in a wavelength region of 360 nm to 780 nm, for example 400 nm to 780 nm and emits fluorescence in a wavelength region of 500 nm to 700 nm, for example 500 nm to 580 nm, or emits fluorescence in a wavelength region of 600 nm to 680 nm. That is, the quantum dots may have a maximum fluorescence emission wavelength (fluorescence λₑₘ) at 500 nm to 680 nm.

The quantum dots may each independently have a full width at half maximum (FWHM) of 20 nm to 100 nm, for example 20 nm to 50 nm. If the quantum dots have a full width at half maximum (FWHM) of the ranges, color reproducibility is increased when used as a color material in a color filter due to high color purity.

The quantum dots may each independently be an organic material, an inorganic material, or a hybrid (mixture) of an organic material and an inorganic material.

The quantum dots may each independently be composed of a core and a shell surrounding the core, and the core and the shell may each independently have a structure of a core, core/shell, core/first shell/second shell, alloy, alloy/shell, or the like, which is composed of Group II-IV, Group III-V, and the like, but are not limited thereto.

For example, the core may include at least at least one material selected from CdS, CdSe, CdTe, ZnS, ZnSe, ZnTe, HgS, HgSe, HgTe, GaN, GaP, GaAs, InP, InAs, and an alloy thereof, but is not necessarily limited thereto. The shell surrounding the core may include at least at least one material selected from CdSe, ZnSe, ZnS, ZnTe, CdTe, PbS, TiO, SrSe, HgSe, and an alloy thereof, but is not necessarily limited thereto.

Since an interest in an environment has been recently much increased over the whole world and a restriction of a toxic material also has been fortified, in an embodiment, a cadmium-free light emitting material (InP/ZnS, InP/ZnSe/ZnS, etc.) having little low quantum efficiency (quantum yield) but being environmentally-friendly instead of a light emitting material having a cadmium-based core is used, but not necessarily limited thereto.

In the case of the quantum dots of the core/shell structure, an entire size including the shell (an average particle diameter) may be 1 nm to 15 nm, for example, 5 nm to 15 nm.

For example, the quantum dots may each independently include red quantum dots, green quantum dots, or a combination thereof. The red quantum dots may each independently have an average particle diameter of 10 nm to 15 nm. The green quantum dots may each independently have an average particle diameter of 5 nm to 8 nm.

On the other hand, for dispersion stability of the quantum dots, the curable composition according to an embodiment may further include a dispersant. The dispersant helps uniform dispersibility of light conversion materials such as quantum dots in the curable composition and may include a non-ionic, anionic, or cationic dispersant. Specifically, the dispersant may be polyalkylene glycol or esters thereof, a polyoxy alkylene, a polyhydric alcohol ester alkylene oxide addition product, an alcohol alkylene oxide addition product, a sulfonate ester, a sulfonate salt, a carboxylate ester, a carboxylate salt, alkyl amide alkylene oxide addition product, alkyl amine and the like, and they may be used alone or in a mixture of two or more. The dispersant may be used in an amount of 0.1 wt % to 100 wt %, for example 10 wt % to 20 wt % based on a solid content of the light conversion material such as quantum dots.

### Polymerizable Compound

The curable composition according to an embodiment may include a polymerizable compound, and the polymerizable compound may have a carbon-carbon double bond at its terminal end.

The polymerizable compound having the carbon-carbon double bond at the terminal end may be included in an amount of 40 wt % to 95 wt %, for example, 50 wt % to 90 wt %, based on a total amount of the solvent-free curable composition. If the polymerizable compound having the carbon-carbon double bond at the terminal end is included within the ranges, a solvent-free curable composition having a viscosity that enables ink-jetting may be prepared and the quantum dots in the prepared solvent-free curable composition may have improved dispersibility, thereby improving optical characteristics.

For example, the polymerizable compound having the carbon-carbon double bond at the terminal end may have a molecular weight of 170 g/mol to 1,000 g/mol. If the polymerizable compound having the carbon-carbon double bond at the terminal end has a molecular weight within the range, it may be advantageous for ink-jetting because it does not increase a viscosity of the composition without hindering the optical characteristics of the quantum dots.

For example, the polymerizable compound having the carbon-carbon double bond at the terminal end may be represented by Chemical Formula 2, but is not necessarily limited thereto.

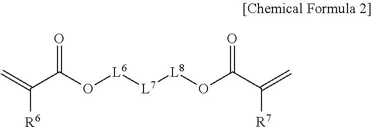

In Chemical Formula 2,
R⁶ and R⁷ are each independently a hydrogen atom or a substituted or unsubstituted C1 to C10 alkyl group,
L⁶ and L⁸ are each independently a single bond or a substituted or unsubstituted C1 to C10 alkylene group, and
L⁷ is a substituted or unsubstituted C1 to C10 alkylene group, a substituted or unsubstituted C3 to C20 cycloalkylene group, or an ether group (*—O—*).

For example, the polymerizable compound having the carbon-carbon double bond at the terminal end may be represented by Chemical Formula 2-1 or Chemical Formula 2-2, but is not necessarily limited thereto.

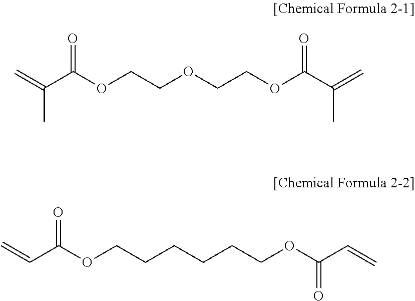

For example, the monomer having the carbon-carbon double bond at the terminal end may further include ethylene glycoldiacrylate, triethylene glycoldiacrylate, 1,4-butanedioldiacrylate, 1,6-hexanedioldiacrylate, neopentylglycoldiacrylate, pentaerythritoldiacrylate, pentaerythritoltriacrylate, dipentaerythritoldiacrylate, dipentaerythritoltriacrylate, dipentaerythritolpentaacrylate, pentaerythritolhexaacrylate, bisphenol A diacrylate, trimethylolpropanetriacrylate, novolac epoxyacrylate, ethylene glycoldimethacrylate, triethylene glycoldimethacrylate, propylene glycoldimethacrylate, 1,4-butanedioldimethacrylate, 1,6-hexanedioldimethacrylate, or a combination thereof in addition to the aforementioned compound of Chemical Formula 2-1 or Chemical Formula 2-2.

In addition, together with the polymerizable compound having the carbon-carbon double bond at the terminal end, a generally-used monomer of a conventional thermosetting or photocurable composition may be further included. For example the monomer further include an oxetane-based compound such as bis[1-ethyl(3-oxetanyl)]methyl ether, and the like.

In addition, when the curable composition includes a solvent, based on a total amount of the curable composition, the polymerizable compound may be included in an amount of 1 wt % to 20 wt %, 1 wt % to 15 wt %, for example, 5 wt % to 15 wt %. When the polymerizable compound is included within the above range, optical characteristics of the quantum dots may be improved.

### Light Diffusing Agent

The curable composition according to an embodiment may further include a light diffusing agent.

For example, the light diffusing agent may include barium sulfate (BaSO₄), calcium carbonate (CaCO3), titanium dioxide (TiO₂), zirconia (ZrO₂), or a combination thereof.

The light diffusing agent may reflect unabsorbed light in the aforementioned quantum dots and allows the quantum dots to absorb the reflected light again. That is, the light diffusing agent may increase an amount of light absorbed by the quantum dots and increase light conversion efficiency of the curable composition.

The light diffusing agent may have an average particle diameter (D₅₀) of 150 nm to 250 nm, and specifically 180 nm to 230 nm. If the average particle diameter of the light diffusing agent is within the ranges, it may have a better light diffusing effect and increase light conversion efficiency.

The light diffusing agent may be included in an amount of 1 wt % to 20 wt %, for example, 2 wt % to 15 wt %, for example, 3 wt % to 10 wt % based on a total amount of the curable composition. If the light diffusing agent is included in an amount of less than 1 wt % based on a total amount of the curable composition, it is difficult to expect a light conversion efficiency improvement effect due to the use of the light diffusing agent, while if it is included in an amount of greater than 20 wt %, there is a possibility that the quantum dots may be precipitated.

### Polymerization Initiator

The curable composition according to an embodiment may further include a polymerization initiator, for example, a photopolymerization initiator, a thermal polymerization initiator, or a combination thereof.

The photopolymerization initiator is a generally-used initiator for a photosensitive resin composition, for example an acetophenone-based compound, a benzophenone-based compound, a thioxanthone-based compound, a benzoin-based compound, a triazine-based compound, an oxime-based compound, an aminoketone-based compound, and the like, but is not necessarily limited thereto.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may be benzophenone, benzoyl benzoate, benzoyl methyl benzoate, 4-phenyl benzophenone, hydroxybenzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin-based compound may be benzoin, benzoin methyl ether, benzoin ethyl ether, benzoin isopropyl ether, benzoin isobutyl ether, benzyldimethylketal, and the like.

Examples of the triazine-based compound may be 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloro methyl)-s-triazine, bis(trichloromethyl)-6-styryl-s-triazine, 2-(naphtho1-yl)-4,6-bis(trichloromethyl)-s-triazine, 2-(4-methoxynaphtho1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime-based compound may be O-acyloxime-based compound, 2-(O-benzoyloxime)-1-[4-(phenylthio)phenyl]-1,2-octandione, 1-(O-acetyloxime)-1-[9-ethyl-6-(2-methylbenzoyl)-9H-carbazol-3-yllethanone, 0-ethoxycarbonyl-a-oxyamino-1-phenylpropan-1-one, and the like. Specific examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

Examples of the aminoketone-based compound may be 2-benzyl-2-dimethylamino-1-(4-morpholinophenyl)-butanone-1, and the like.

The photopolymerization initiator may further include a carbazole-based compound, a diketone-based compound, a sulfonium borate-based compound, a diazo-based compound, an imidazole-based compound, a biimidazole-based compound, and the like, besides the compounds.

The photopolymerization initiator may be used with a photosensitizer capable of causing a chemical reaction by absorbing light and becoming excited and then, transferring its energy.

Examples of the photosensitizer may be tetraethylene glycol bis-3-mercapto propionate, pentaerythritol tetrakis-3-mercapto propionate, dipentaerythritol tetrakis-3-mercapto propionate, and the like.

Examples of the thermal polymerization initiator may be peroxide, specifically benzoyl peroxide, dibenzoyl peroxide, lauryl peroxide, dilauryl peroxide, di-tert-butyl peroxide, cyclohexane peroxide, methyl ethyl ketone peroxide, hydroperoxide (e.g., tert-butyl hydroperoxide, cumene hydroperoxide), dicyclohexyl peroxydicarbonate, 2,2-azo-bis(isobutyronitrile), t-butyl perbenzoate, and the like, for example 2,2′-azobis-2-methylpropinonitrile, but are not necessarily limited thereto and any of which is well known in the art may be used.

The polymerization initiator may be included in an amount of 0.1 wt % to 5 wt %, for example 1 wt % to 4 wt % based on a total amount of the curable composition. If the polymerization initiator is included in the ranges, it is possible to obtain excellent reliability due to sufficient curing during exposure or thermal curing and to prevent deterioration of transmittance due to non-reaction initiators, thereby preventing deterioration of optical characteristics of the quantum dots.

### Binder Resin

The curable composition according to an embodiment may further include a binder resin.

The binder resin may include an acrylic resin, a cardo-based resin, an epoxy resin, or a combination thereof.

The acrylic resin may be a copolymer of a first ethylenic unsaturated monomer and a second ethylenic unsaturated monomer that is copolymerizable therewith, and may be resin including at least one acryl-based repeating unit.

Specific examples of the acryl-based resin may be polybenzylmethacrylate, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, but are not limited thereto, and may be used alone or as a mixture of two or more.

A weight average molecular weight of the acryl-based binder resin may be 5,000 g/mol to 15,000 g/mol. If the acrylic resin has a weight average molecular weight within the ranges, close contacting properties to a substrate, physical and chemical properties are improved, and a viscosity is appropriate.

An acid value of the acrylic resin may be 80 mgKOH/g to 130 mgKOH/g. If the acrylic resin has an acid value within the ranges, excellent resolution of a pixel may be obtained.

The cardo-based resin may be used in a conventional curable resin (or photosensitive resin) composition, for example, those suggested in Korean Patent Publication No. 10-2018-0067243 may be used, but is not limited thereto.

The cardo-based resin may be, for example prepared by mixing at least two of a fluorene-containing compound such as 9,9-bis(4-oxiranylmethoxyphenyl) fluorene; an anhydride compound such as benzenetetracarboxylic acid dianhydride, naphthalenetetracarboxylic acid dianhydride, biphenyltetracarboxylic acid dianhydride, benzophenonetetracarboxylic acid dianhydride, pyromellitic dianhydride, cyclobutanetetracarboxylic acid dianhydride, perylenetetracarboxylic acid dianhydride, tetrahydrofurantetracarboxylic acid dianhydride, and tetrahydrophthalic anhydride; a glycol compound such as ethylene glycol, propylene glycol, and polyethylene glycol; an alcohol compound such as methanol, ethanol, propanol, n-butanol, cyclohexanol, and benzylalcohol; a solvent-based compound such as propylene glycol methylethylacetate, and N-methylpyrrolidone; a phosphorus compound such as triphenylphosphine; and an amine or ammonium salt compound such as tetramethylammonium chloride, tetraethylammonium bromide, benzyldiethylamine, triethylamine, tributylamine, or benzyltriethylammonium chloride.

A weight average molecular weight of the cardo-based binder resin may be 500 g/mol to 50,000 g/mol, for example 1,000 g/mol to 30,000 g/mol. When the weight average molecular weight of the cardo-based binder resin is within the ranges, a satisfactory pattern may be formed without a residue during a production of a cured layer and without losing a film thickness during development of the solvent-type curable composition.

If the binder resin is a cardo-based resin, the curable composition including the same, particularly the photosensitive resin composition has excellent developability and sensitivity during photo-curing and thus, fine pattern-forming capability.

The epoxy resin may be a thermally polymerizable monomer or oligomer, and may include a compound having a carbon-carbon unsaturated bond and a carbon-carbon cyclic bond.

The epoxy resin may further include a bisphenol A epoxy resin, a bisphenol F epoxy resin, a phenol novolac epoxy resin, a cyclic aliphatic epoxy resin, and an aliphatic polyglycidyl ether, but is not necessarily limited thereto.

As commercially available products of the compounds, a bisphenyl epoxy resin may be YX4000, YX4000H, YL6121H, YL6640, or YL6677 of Yuka Shell Epoxy Co., Ltd.; a cresol novolac epoxy resin may be EOCN-102, EOCN-103S, EOCN-104S, EOCN-1020, EOCN-1025, and EOCN-1027 of Nippon Kayaku Co., Ltd. and EPIKOTE 180S75, and the like of Yuka Shell Epoxy Co., Ltd.; a bisphenol A epoxy resin may be EPIKOTE 1001, 1002, 1003, 1004, 1007, 1009, 1010, and 828 of Yuka Shell Epoxy Co., Ltd.; a bisphenol F epoxy resin may be EPIKOTE 807 and 834 of Yuka Shell Epoxy Co., Ltd.; a phenol novolac epoxy resin may be EPIKOTE 152, 154, or 157H65 of Yuka Shell Epoxy Co. and EPPN 201, 202 of Nippon Kayaku Co., Ltd.; a cyclic aliphatic epoxy resin may be CY175, CY177, and CY179 of CIBA-GEIGY A.G Corp., ERL-4234, ERL-4299, ERL-4221 and ERL-4206 of U.C.C., Showdyne 509 of Showa Denko K.K., Araldite CY-182, CY-192 and CY-184 of CIBA-GEIGY A.G Corp., EPICLON 200 and 400 of Dainippon Ink & Chemicals Inc., EPIKOTE 871 and 872, and EP1032H60 of Yuka Shell Epoxy Co., Ltd., ED-5661 and ED-5662 of Celanese Coating Corporation; an aliphatic polyglycidylether may be EPIKOTE 190P and 191P of Yuka Shell Epoxy Co., Ltd., EPOLITE 100MF of Kyoeisha Yushi Kagaku Kogyo Co., Ltd., EPIOL TMP of Nihon Yushi K. K., and the like.

For example, when the curable composition according to an embodiment is a solvent-free curable composition, the binder resin may be included in an amount of 0.5 wt % to 10 wt %, for example, 1 wt % to 5 wt %, based on a total amount of the curable composition. In this case, the heat resistance and the chemical resistance of the solvent-free curable composition may be improved, as well as the storage stability of the composition.

For example, when the curable composition according to an embodiment is a curable composition including a solvent, the binder resin may be included in an amount of 1 wt % to 30 wt %, for example, 3 wt % to 20 wt %, based on a total amount of the curable composition. In this case, it may improve pattern characteristics, heat resistance, and chemical resistance.

### Other Additives

For stability and dispersion improvement of the quantum dots, the curable composition according to an embodiment may further include a polymerization inhibitor.

The polymerization inhibitor may include a hydroquinone-based compound, a catechol-based compound, or a combination thereof, but is not necessarily limited thereto. When the curable composition according to an embodiment further includes the hydroquinone-based compound, the catechol-based compound, or the combination thereof, room temperature cross-linking during exposure after coating the curable composition may be prevented.

For example, the hydroquinone-based compound, the catechol-based compound, or the combination thereof may be hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′) aluminum, or a combination thereof, but are not necessarily limited thereto.

The hydroquinone-based compound, the catechol-based compound, or the combination thereof may be used in a form of dispersion. The polymerization inhibitor in a form of dispersion may be included in an amount of 0.001 wt % to 3 wt %, for example 0.01 wt % to 2 wt % based on a total amount of the curable composition. If the polymerization inhibitor is included in the ranges, passage of time at room temperature may be solved and simultaneously sensitivity deterioration and surface delamination phenomenon may be prevented.

In addition, the curable composition according to an embodiment may further include malonic acid; 3-amino-1,2-propanediol; a silane-based coupling agent; a leveling agent; a fluorine-based surfactant; or a combination thereof in order to improve heat resistance and reliability.

For example, the curable composition according to embodiment may further include a silane-based coupling agent having a reactive substituent such as a vinyl group, a carboxyl group, a methacryloxy group, an isocyanate group, an epoxy group, and the like in order to improve close contacting properties with a substrate.

Examples of the silane-based coupling agent may be trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-epoxycyclohexyl)ethyltrimethoxysilane, and the like, and these may be used alone or in a mixture of two or more.

The silane-based coupling agent may be used in an amount of 0.01 parts by weight to 10 parts by weight based on 100 parts by weight of the curable composition. If the silane-based coupling agent is included within the range, close contacting properties, storage capability, and the like are improved.

In addition, the curable composition may further include a surfactant, for example a fluorine-based surfactant as needed in order to improve coating properties and inhibit generation of spots, that is, improve leveling performance.

The fluorine-based surfactant may have a low weight average molecular weight of 4,000 g/mol to 10,000 g/mol, and specifically 6,000 g/mol to 10,000 g/mol. In addition, the fluorine-based surfactant may have a surface tension of 18 mN/m to 23 mN/m (measured in a 0.1% polyethylene glycol monomethylether acetate (PGMEA) solution). If the fluorine-based surfactant has a weight average molecular weight and a surface tension within the ranges, leveling performance may be further improved, and excellent characteristics may be provided when slit coating as high-speed coating is applied since film defects may be less generated by preventing a spot generation during the high-speed coating and suppressing a vapor generation.

Examples of the fluorine-based surfactant may be, BM-1000®, and BM-1100® (BM Chemie Inc.); MEGAFACE F 142D®, F 172®, F 173®, and F 183® Dainippon Ink Kagaku Kogyo Co., Ltd.); FULORAD FC-135®, FULORAD FC-170C®, FULORAD FC-430®, and FULORAD FC-431® (Sumitomo 3M Co., Ltd.); SURFLON S-112®, SURFLON S-113®, SURFLON S-131®, SURFLON S-141®, and SURFLON S-145® (ASAHI Glass Co., Ltd.); and SH-28PA®, SH-190®, SH-193®, SZ-6032®, and SF-8428®, and the like (Toray Silicone Co., Ltd.); F-482, F-484, F-478, F-554 and the like of DIC Co., Ltd.

In addition, the curable composition according to an embodiment may include a silicone-based surfactant in addition to the fluorine-based surfactant. Specific examples of the silicone-based surfactant may be TSF400, TSF401, TSF410, TSF4440, and the like of Toshiba silicone Co., Ltd., but are not limited thereto.

The surfactant may be included in an amount of 0.01 parts by weight to 5 parts by weight, for example 0.1 parts by weight to 2 parts by weight based on 100 parts by weight of the curable composition. If the surfactant is included within the ranges, foreign materials are less produced in a sprayed composition.

In addition, the curable composition according to an embodiment may further include other additives such as an antioxidant, a stabilizer, and the like in a predetermined amount, unless properties are deteriorated.

### Solvent

Meanwhile, the curable composition according to an embodiment may further include a solvent.

The solvent may for example include alcohols such as methanol, ethanol, and the like; glycol ethers such as ethylene glycol methylether, ethylene glycol ethylether, propylene glycol methylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol monomethylether acetate, propylene glycol propylether acetate, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; hydroxy acetic acid alkyl esters such as methyl hydroxyacetate, ethyl hydroxyacetate, butyl hydroxyacetate, and the like; acetic acid alkoxyalkyl esters such as methoxymethyl acetate, methoxyethyl acetate, methoxybutyl acetate, ethoxymethyl acetate, ethoxyethyl acetate, and the like; 3-hydroxypropionic acid alkyl esters such as methyl 3-hydroxypropionate, ethyl 3-hydroxypropionate, and the like; 3-alkoxypropionic acid alkyl esters such as methyl 3-methoxypropionate, ethyl 3-methoxypropionate, ethyl 3-ethoxypropionate, methyl 3-ethoxypropionate, and the like; 2-hydroxypropionic acid alkyl ester such as methyl 2-hydroxypropionate, ethyl 2-hydroxypropionate, propyl 2-hydroxypropionate, and the like; 2-alkoxypropionic acid alkyl esters such as methyl 2-methoxypropionate, ethyl 2-methoxypropionate, ethyl 2-ethoxypropionate, methyl 2-ethoxypropionate, and the like; 2-hydroxy-2-methylpropionic acid alkyl esters such as methyl 2-hydroxy-2-methylpropionate, ethyl 2-hydroxy-2-methylpropionate, and the like; 2-alkoxy-2-methylpropionic acid alkyl esters such as methyl 2-methoxy-2-methylpropionate, ethyl 2-ethoxy-2-methylpropionate, and the like; esters such as 2-hydroxyethyl propionate, 2-hydroxy-2-methylethyl propionate, hydroxyethyl acetate, methyl 2-hydroxy-3-methylbutanoate, and the like; or ketonate esters such as ethyl pyruvate, and the like, and in addition, may be N-methylformamide, N, N-dimethyl formamide, N-methylformanilide, N-methylacetamide, N, N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, y-butyrolactone, ethylene carbonate, propylene carbonate, phenyl cellosolve acetate, and the like, but is not limited thereto.

For example, the solvent may be desirably glycol ethers such as ethylene glycol monoethylether, ethylene diglycolmethylethylether, and the like; ethylene glycol alkylether acetates such as ethyl cellosolve acetate, and the like; esters such as 2-hydroxy ethyl propionate, and the like; carbitols such as diethylene glycol monomethylether, and the like; propylene glycol alkylether acetates such as propylene glycol monomethylether acetate, propylene glycol propylether acetate, and the like; alcohols such as ethanol, and the like, or a combination thereof.

For example, the solvent may be a polar solvent including propylene glycol monomethylether acetate, dipropylene glycol methylether acetate, ethanol, ethylene glycoldimethylether, ethylenediglycolmethylethylether, diethylene glycoldimethylether, 2-butoxyethanol, N-methylpyrrolidine, N-ethylpyrrolidine, propylene carbonate, γ-butyrolactone, or a combination thereof.

The solvent may be included in an amount of 40 wt % to 80 wt %, for example, 45 wt % to 80 wt %, based on a total amount of the curable composition. If the solvent is within the range, the solvent-type curable composition has appropriate viscosity and thus may have excellent coating property when coated in a large area through spin-coating and slit-coating.

Another embodiment provides a curable composition, for example, a cured layer produced using the curable composition, and a display device including the cured layer.

One of methods of producing the cured layer may include coating the curable composition and solvent-type curable composition on a substrate using an ink-jet spraying method to form a pattern (S1); and curing the pattern (S2).

### (S1) Formation of Pattern

The curable composition may desirably be coated to be 0.5 μm to 20 μm on a substrate in an ink-jet spraying method. The ink-jet spraying method may form a pattern by spraying a single color per each nozzle and thus repeating the spraying as many times as the needed number of colors, but the pattern may be formed by simultaneously spraying the needed number of colors through each ink-jet nozzle in order to reduce processes.

### (S2) Curing

The obtained pattern is cured to obtain a pixel. Herein, the curing method may be thermal curing or photocuring process. The thermal curing process may be performed at greater than or equal to 100° C., desirably, in a range of 100° C. to 300° C., and more desirably, in a range of 160° C. to 250° C. The photocuring process may include irradiating an actinic ray such as a UV ray of 190 nm to 450 nm, for example 200 nm to 400 nm. As a light source used for irradiation, a low-pressure mercury lamp, high-pressure mercury lamp, ultra-high-pressure mercury lamp, metal halide lamp, argon gas laser, i-line, KrF, ArF, I-ArF, EUV, X-ray, electron beam, etc. may be used as needed.

The other method of producing the cured layer may include producing a cured layer using the aforementioned curable composition or solvent-type curable composition by a lithographic method as follows.

### (1) Coating and Film Formation

The curable composition is coated to have a desired thickness, for example, a thickness ranging from 2 μm to 10 μm, on a substrate which undergoes a predetermined pretreatment, using a spin or slit coating method, a roll coating method, a screen-printing method, an applicator method, and the like. Then, the coated substrate is heated at a temperature of 70° C. to 90° C. for 1 minute to 10 minutes to remove a solvent and to form a film.

### (2) Exposure

The resultant film is irradiated by an actinic ray such as a UV ray of 190 nm to 450 nm, for example 200 nm to 400 nm after putting a mask with a predetermined shape to form a desired pattern. As a light source, a low-pressure mercury lamp, high-pressure mercury lamp, ultra high-pressure mercury lamp, metal halide lamp, argon gas laser, i-line, KrF, ArF, I-ArF, EUV, X-ray, electron beam, etc. may be used as needed.

Exposure process uses, for example, a light dose of 500 mJ/cm² or less (with a 365 nm sensor) when a high-pressure mercury lamp is used. However, the light dose may vary depending on types of each component of the curable composition, its combination ratio, and a dry film thickness.

### (3) Development

After the exposure process, an alkali aqueous solution is used to develop the exposed film by dissolving and removing an unnecessary part except the exposed part, forming an image pattern. In other words, when the alkali developing solution is used for the development, an unexposed region is dissolved, and an image color filter pattern is formed.

### (4) Post-Treatment

The developed image pattern may be heated again or irradiated by an actinic ray and the like for curing, in order to accomplish excellent quality in terms of heat resistance, light resistance, close contacting properties, crack-resistance, chemical resistance, high strength, storage stability, and the like.

### MODE FOR INVENTION

Hereinafter, the present invention is illustrated in more detail with reference to examples. These examples, however, are not in any sense to be interpreted as limiting the scope of the invention.

### Synthesis of Surface-Modifying Material

### Synthesis Example 1

A compound represented by Chemical Formula E-1 (Sigma-Aldrich Co., Ltd.) and a compound represented by Chemical Formula E-2 were reacted in an equivalence ratio of 1:7 at 70° C. for 10 hours, synthesizing a polymer (a weight average molecular weight: 4,000 g/mol) including a structural unit represented by Chemical Formula E-3.

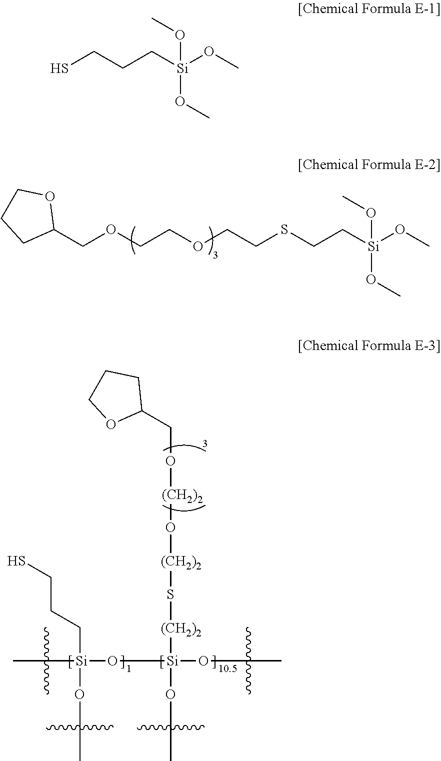

(Reaction Scheme of synthesis of the compound represented by Chemical Formula E-2)

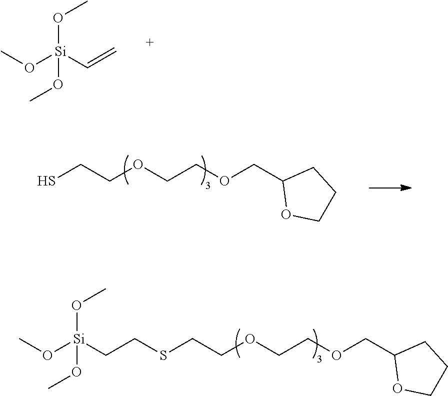

### Synthesis Example 2

A surface-modifying material was synthesized in the same manner as in Synthesis Example 1 except that the compound represented by Chemical Formula E-1 and the compound represented by Chemical Formula E-2 were reacted in an equivalence ratio of 1:1.5.

### Synthesis Example 3

A surface-modifying material was synthesized in the same manner as in Synthesis Example 1 except that the compound represented by Chemical Formula E-1 and the compound represented by Chemical Formula E-2 were reacted in an equivalence ratio of 1:3.

### Synthesis Example 4

A surface-modifying material was synthesized in the same manner as in Synthesis Example 1 except that the compound represented by Chemical Formula E-1 and the compound represented by Chemical Formula E-2 were reacted in an equivalence ratio of 1:5.

### Synthesis Example 5

A surface-modifying material was synthesized in the same manner as in Synthesis Example 1 except that the compound represented by Chemical Formula E-1 and the compound represented by Chemical Formula E-2 were reacted in an equivalence ratio of 1:1.

### Synthesis Example 6

A surface-modifying material was synthesized in the same manner as in Synthesis Example 1 except that the compound represented by Chemical Formula E-1 and the compound represented by Chemical Formula E-2 were reacted in an equivalence ratio of 1:10.

### Comparative Synthesis Example 1

A surface-modifying material was synthesized in the same manner as in Synthesis Example 1 except that the compound represented by Chemical Formula E-2 was not used.

### Comparative Synthesis Example 2

A surface-modifying material was synthesized in the same manner as in Synthesis Example 1 except that the compound represented by Chemical Formula E-1 was not used.

### Comparative Synthesis Example 3

Tetraethyl orthosilicate (Sigma-Aldrich Co., Ltd.) was used as a surface-modifying material.

### (Preparation of Surface-Modified Quantum Dots)

### Preparation Example 1

After putting a magnetic bar in a 3-necked round bottom flask, a green quantum dot dispersion solution (a quantum dot solid content: 23 wt %, InP/ZnSe/ZnS, Hansol Chemical) was added thereto. Subsequently, the surface-modifying material of Synthesis Example 1 was added thereto and then, stirred at 80° C. under a nitrogen atmosphere. When a reaction was completed, the quantum dot reaction was cooled to room temperature (23° C.) and then, added to cyclohexane, catching precipitates. The precipitates were separated from the cyclohexane through the centrifugation and then, sufficiently dried in a vacuum oven for 24 hours, obtaining surface-modified green quantum dots.

### Preparation Example 2

Surface-modified green quantum dots were prepared in the same manner as in Preparation Example 1 except that the surface-modifying material of Synthesis Example 2 was used instead of the surface-modifying material of Synthesis Example 1.

### Preparation Example 3

Surface-modified green quantum dots were prepared in the same manner as in Preparation Example 1 except that the surface-modifying material of Synthesis Example 3 was used instead of the surface-modifying material of Synthesis Example 1.

### Preparation Example 4

Surface-modified green quantum dots were prepared in the same manner as in Preparation Example 1 except that the surface-modifying material of Synthesis Example 4 was used instead of the surface-modifying material of Synthesis Example 1.

### Preparation Example 5

Surface-modified green quantum dots were prepared in the same manner as in Preparation Example 1 except that the surface-modifying material of Synthesis Example 5 was used instead of the surface-modifying material of Synthesis Example 1.

### Preparation Example 6

Surface-modified green quantum dots were prepared in the same manner as in Preparation Example 1 except that the surface-modifying material of Synthesis Example 6 was used instead of the surface-modifying material of Synthesis Example 1.

### Comparative Preparation Example 1

Surface-modified green quantum dots were prepared in the same manner as in Preparation Example 1 except that the surface-modifying material of Comparative Synthesis Example 1 was used instead of the surface-modifying material of Synthesis Example 1.

### Comparative Preparation Example 2

Surface-modified green quantum dots were prepared in the same manner as in Preparation Example 1 except that the surface-modifying material of Comparative Synthesis Example 2 was used instead of the surface-modifying material of Synthesis Example 1.

### Comparative Preparation Example 3

Surface-modified green quantum dots were prepared in the same manner as in Preparation Example 1 except that the surface-modifying material of Comparative Synthesis Example 3 was used instead of the surface-modifying material of Synthesis Example 1.

### (Preparation of Curable Compositions)

Based on each of the following components, curable compositions according to Examples 1 to 6 and Comparative Examples 1 to 3 were prepared.

### (A) Quantum Dots

(A-1) Surface-modified green quantum dots prepared from Preparation Example 1

(A-2) Surface-modified green quantum dots prepared from Preparation Example 2

(A-3) Surface-modified green quantum dots prepared from Preparation Example 3

(A-4) Surface-modified green quantum dots prepared from Preparation Example 4

(A-5) Surface-modified green quantum dots prepared from Preparation Example 5

(A-6) Surface-modified green quantum dots prepared from Preparation Example 6

(A-7) Surface-modified green quantum dots prepared from Comparative Preparation Example 1

(A-8) Surface-modified green quantum dots prepared from Comparative Preparation Example 2

(A-9) Surface-modified green quantum dots prepared from Comparative Preparation Example 3

### (B) Polymerizable Compound

Compound represented by Chemical Formula 2-2 (1,6-Hexanediol diacrylate, Miwon Specialty Chemical)

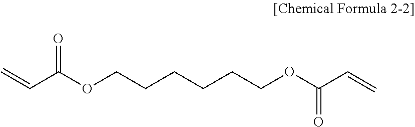 [SMILES: C=CC(=O)OCCCCCCOC(=O)C=C]

### (C) Photopolymerization Initiator

TPO-L (Polynetron Co.)

### (D) Light Diffusing Agent

Titanium dioxide dispersion (rutile type TiO₂; D50 (180 nm), solid content 50 wt %, Iridos Co., Ltd.)

### (E) Polymerization Inhibitor

Methylhydroquinone (TOKYO CHEMICAL Co., Ltd.)

### Examples 1 to 6 and Comparative Examples 1 to 3

Specifically, each of the surface-modified green quantum dots and a polymerizable compound were mixed and stirred for 12 hours. Subsequently, a polymerization inhibitor was added thereto and then, stirred for 5 minutes. Then, a photoinitiator, if needed, was added thereto and then, a light diffusing agent was added thereto.

(Taking Example 1 as an example, 41 g of the surface-modified green quantum dots and 41 g of a compound represented by Chemical Formula 2-2 as the polymerizable compound were mixed and then, stirred to prepare green quantum dot dispersion, 12.45 g of another curing monomer represented by Chemical Formula 2-2 and 0.05 g of a polymerization inhibitor were added thereto and then, stirred for 5 minutes, and subsequently, 3 g of a photoinitiator and 4 g of a light diffusing agent were added thereto and then, stirred, preparing a curable composition.)

Specific compositions thereof are shown in Table 1.

TABLE 1
(unit: wt %)

| | Quantum dots | | | | | | | | | | | | Light |
|---|---|---|---|---|---|---|---|---|---|---|---|---|---|
| | (A - | (A - | (A - | (A - | (A - | (A - | (A - | (A - | (A - | Polymerizable | Polymerization | Photo | diffusing |
| | 1) | 2) | 3) | 4) | 5) | 6) | 7) | 8) | 9) | compound | inhibitor | initiator | agent |
| Example 1 | 41 | — | — | — | — | — | — | — | — | 53.45 | 0.05 | 1.5 | 4 |
| Example 2 | — | 41 | — | — | — | — | — | — | — | 53.45 | 0.05 | 1.5 | 4 |
| Example 3 | — | — | 41 | — | — | — | — | — | — | 53.45 | 0.05 | 1.5 | 4 |
| Example 4 | — | — | — | 41 | — | — | — | — | — | 53.45 | 0.05 | 1.5 | 4 |
| Example 5 | — | — | — | — | 41 | — | — | — | — | 53.45 | 0.05 | 1.5 | 4 |
| Example 6 | — | — | — | — | — | 41 | — | — | — | 53.45 | 0.05 | 1.5 | 4 |
| Comparative | — | — | — | — | — | — | 41 | — | — | 53.45 | 0.05 | 1.5 | 4 |
| Example 1 | | | | | | | | | | | | | |
| Comparative | — | — | — | — | — | — | — | 41 | — | 53.45 | 0.05 | 1.5 | 4 |
| Example 2 | | | | | | | | | | | | | |
| Comparative | — | — | — | — | — | — | — | — | 41 | 53.45 | 0.05 | 1.5 | 4 |
| Example 3 | | | | | | | | | | | | | |

### Evaluation: Evaluation of Heat Resistance/Light Resistance

### Characteristics of Curable Compositions

Each of the curable compositions of Examples 1 to 6 and Comparative Examples 1 to 3 was evaluated with respect to heat resistance/light resistance characteristics, and the results are shown in Table 2.

Specifically, each of the prepared curable compositions by 2 mL was spin-coated at 1,500 rpm on a glass substrate and exposed to light with 5 J for 9 seconds by using a nitrogen UV exposer to form a QD film (9 μm), and the QD film was measured with respect to an initial blue light conversion rate and quantum efficiency (EQE) after the exposure by using a light efficiency meter (QE-2100, Otsuka Electronics Co., Ltd.).

Subsequently, the substrate on which the QD film was formed was baked on a hot plate at 180° C. under a nitrogen atmosphere for 30 minutes and cooled at room temperature (23° C.) for 1 hour. Then, the light efficiency meter was used to measure a blue light conversion rate again, which was used to calculate a heat process retention rate (light resistance rate, %) according to the following calculation equation, and then, time taken until the heat process rate decreased to 90% was measured to obtain light resistance reliability.

$$Heat process retention rate ( \% ) = [ light conversion rate ( after baking ) / initial light conversion rate ] * 100$$

TABLE 2

| | Quantum efficiency | Light resistance |
|---|---|---|
| | after exposure (%) | reliability (hr) |
| Example 4 | 38.7 | 186 |
| Example 1 | 33.6 | 158 |
| Example 2 | 37.5 | 160 |
| Example 3 | 37.1 | 167 |
| Example 5 | 33.3 | 157 |

| | |
|---|---|
| Example 6 | Difficult in L/E conversion due to |
| | low SH equivalent in ligand |
| Comparative Example 1 | Unable to prepare curable composition |
| | due to dispersion deterioration |
| Comparative Example 2 | L/E substitution was unavailable |
| Comparative Example 3 | L/E substitution was unavailable |

Referring to Table 2, the curable compositions of Examples 1 to 6, compared with the curable composition of Comparative Examples 1 to 3, exhibited excellent quantum efficiency (optical characteristics) and light resistance reliability (optical characteristics, processability) at the same time.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

1. A curable composition, comprising
(A) quantum dots including a structural unit represented by Chemical Formula 1; and
(B) a polymerizable compound: 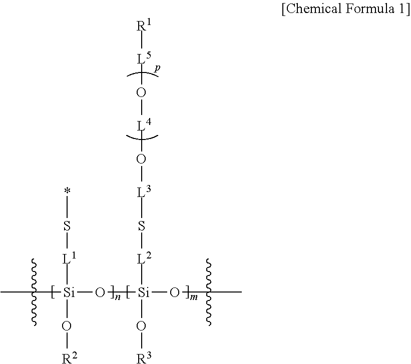
wherein, in Chemical Formula 1,
R¹ is a substituted or unsubstituted C2 to C20 heterocycloalkyl group or a substituted or unsubstituted C6 to C20 aryl group,
R² and R³ are each independently a hydrogen atom or a substituted or unsubstituted C1 to C20 alkyl group,
L¹ to L⁵ are each independently a substituted or unsubstituted C1 to C20 alkylene group,
n and m are each independently 1 to 100,
p is an integer from 1 to 20, and
* is a linking portion with the quantum dots.

2. The curable composition of claim 1, wherein
the n:m has an equivalence ratio of 1:1.5 to 1:9.

3. The curable composition of claim 1, wherein
the substituted or unsubstituted C2 to C20 heterocycloalkyl group is represented by Chemical Formula R-1: 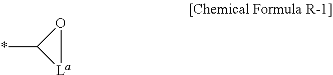
wherein, in Chemical Formula R-1,
L^{a} is a substituted or unsubstituted C2 to C10 alkylene group.

4. The curable composition of claim 1, wherein
the quantum dots are quantum dots surface-modified with a compound having a structure represented by Chemical Formula 3: 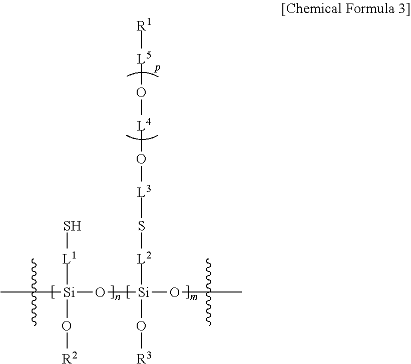
wherein, in Chemical Formula 3,
R¹ is a substituted or unsubstituted C2 to C20 heterocycloalkyl group,
R² and R³ are each independently a hydrogen atom or a substituted or unsubstituted C1 to C20 alkyl group,
L¹ to L⁵ are each independently a substituted or unsubstituted C1 to C20 alkylene group,
n and m are each independently an integer from 1 to 100, and
p is an integer from 1 to 20.

5. The curable composition of claim 1, wherein
the polymerizable compound is represented by Chemical Formula 2: 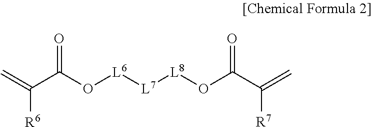
wherein, in Chemical Formula 2,
R⁶ and R⁷ are each independently a hydrogen atom or a substituted or unsubstituted C1 to C10 alkyl group,
L⁶ and L⁸ are each independently a single bond or a substituted or unsubstituted C1 to C10 alkylene group, and
L⁷ is a substituted or unsubstituted C1 to C10 alkylene group, a substituted or unsubstituted C3 to C20 cycloalkylene group, or an ether group (*—O—*).

6. The curable composition of claim 5, wherein
the polymerizable compound is represented by Chemical Formula 2-1 or 2-2:

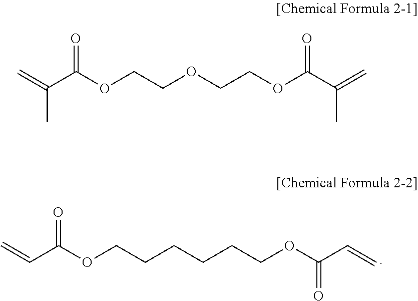

7. The curable composition of claim 1, wherein
the curable composition is a solvent-free curable composition.

8. The curable composition of claim 7, wherein
the solvent-free curable composition includes
5 wt % to 60 wt % of the quantum dots; and
40 wt % to 95 wt % of the polymerizable compound,
based on a total amount of the solvent-free curable composition

9. The curable composition of claim 1, wherein
the curable composition further includes a polymerization initiator, a light diffusing agent, a polymerization inhibitor, or a combination thereof.

10. The curable composition of claim 9, wherein
the light diffusing agent includes barium sulfate, calcium carbonate, titanium dioxide, zirconia, or a combination thereof.

11. The curable composition of claim 1, wherein
the curable composition further includes a solvent.

12. The curable composition of claim 11, wherein
the curable composition includes 1 wt % to 40 wt % of the quantum dots; 1 wt % to 20 wt % of the polymerizable compound; and 40 wt % to 80 wt % of the solvent based on a total weight of the curable composition.

13. The curable composition of claim 1, wherein
the curable composition further includes malonic acid; 3-amino-1,2-propanediol; a silane-based coupling agent; a leveling agent; a fluorine-based surfactant; or a combination thereof.

14. A cured layer produced using the curable composition of claim 1.

15. A display device including the cured layer of claim 14.
